(19) United States
(12) Patent Application Publication
(10) Pub. No.: US 2025/0323609 A1
(43) Pub. Date: Oct. 16, 2025

(54) AMPLIFIER

(71) Applicant: Mitsubishi Electric Corporation, Tokyo (JP)

(72) Inventors: Hiromitsu UTSUMI, Tokyo (JP); Kunihiro SATO, Tokyo (JP)

(73) Assignee: Mitsubishi Electric Corporation, Tokyo (JP)

(21) Appl. No.: 18/779,648

(22) Filed: Jul. 22, 2024

(30) Foreign Application Priority Data
Apr. 12, 2024 (JP) 2024-064992

(51) Int. Cl. H03F 3/213; H03F 1/08; H03F 3/195

(52) U.S. Cl. CPC H03F 3/213; H03F 1/083; H03F 3/195

(57) ABSTRACT

According to an aspect of the first disclosure, an amplifier includes: an input terminal; an output terminal; a pair of amplification paths provided in parallel between the input terminal and the output terminal, each of the pair of amplification paths including a transistor; and a resistive section that connects the pair of amplification paths, wherein the resistive section includes: a resistor having a width which is, compared to on one end side, narrower on another end side; a pair of conductor patterns provided on both sides in a width direction of the resistor and electrically connected to the resistor; and a pair of wirings that connects the one end side of the pair of conductor patterns and the pair of amplification paths.

### BACKGROUND

### Field

The present disclosure relates to an amplifier.

### Background

JP 2013-065938 A discloses a high frequency amplifier including an amplification element divided into a plurality of regions, input matching circuits as many as the number of divisions of the amplification element, and output matching circuits as many as the number of divisions. The high frequency amplifier further includes a first resistor group including one or more removable resistors that connect the input matching circuits adjacent to one another and a second resistor group including one or more removable resistors that connect the output matching circuits adjacent to one another.

It is known that an amplifier including a plurality of amplification paths can cause loop oscillation. JP 2013-065938 discloses a high frequency amplification circuit capable of suppressing oscillation. However, when, for example, a rectangular stabilization resistor having uniform thickness is used for oscillation suppression, a power density distribution of the stabilization resistor is not uniform and it is likely that a location at which electric power is excessively concentrated appears.

### SUMMARY

The present disclosure has been made in order to solve the problem described above, and an object of the present disclosure is to obtain an amplifier that can prevent appearance of a location at which a power density distribution is excessively concentrated in a resistor.

The features and advantages of the present disclosure may be summarized as follows.

According to an aspect of the first disclosure, an amplifier includes: an input terminal; an output terminal; a pair of amplification paths provided in parallel between the input terminal and the output terminal, each of the pair of amplification paths including a transistor; and a resistive section that connects the pair of amplification paths, wherein the resistive section includes: a resistor having a width which is, compared to on one end side, narrower on another end side; a pair of conductor patterns provided on both sides in a width direction of the resistor and electrically connected to the resistor; and a pair of wirings that connects the one end side of the pair of conductor patterns and the pair of amplification paths.

According to an aspect of the second disclosure, an amplifier includes: an input terminal; an output terminal; a pair of amplification paths provided in parallel between the input terminal and the output terminal, each of the pair of amplification paths including a transistor; and a resistive section that connects the pair of amplification paths, wherein the resistive section includes: a resistor having a thickness which is, compared to on one end side, thicker on another end side; a pair of conductor patterns provided on both sides in a direction intersecting a direction from the one end toward the another end of the resistor and electrically connected to the resistor; and a pair of wirings that connects the one end side of the pair of conductor patterns and the pair of amplification paths.

According to an aspect of the third disclosure, an amplifier includes: an input terminal; an output terminal; a pair of amplification paths provided in parallel between the input terminal and the output terminal, each of the pair of amplification paths including a transistor; and a resistive section that connects the pair of amplification paths, wherein the resistive section includes: a resistor; a pair of conductor patterns provided on both sides in a direction intersecting a direction from one end toward another end of the resistor and electrically connected to the resistor; and a pair of wirings that connects the pair of conductor patterns and the pair of amplification paths in a center in the direction from the one end toward the another end of the resistor.

Other and further objects, features and advantages of the disclosure will appear more fully from the following description.

### BRIEF DESCRIPTION OF DRAWINGS

FIG. 1 is a plan view of an amplifier according to a first embodiment.

FIG. 2 is a plan view illustrating a power density distribution of a resistor according to the first embodiment.

FIG. 3 is a diagram illustrating a power density distribution along the center line of the resistor according to the first embodiment.

FIG. 4 is a plan view of an amplifier according to the comparative example.

FIG. 5 is a plan view illustrating a power density distribution of a resistor according to the comparative example.

FIG. 6 is a diagram illustrating a power density distribution along a center line of the resistor according to the comparative example.

FIG. 7 is a plan view of a resistive section according to a second embodiment.

FIG. 8 is a plan view illustrating a power density distribution of the resistor according to the second embodiment.

FIG. 9 is a diagram illustrating a power density distribution along a center line of the resistor according to the second embodiment.

FIG. 10 is a plan view of a resistive section according to a third embodiment.

FIG. 11 is a sectional view obtained by cutting a resistor illustrated in FIG. 10 along a C-C′ straight line.

FIG. 12 is a plan view illustrating a power density distribution of the resistor according to the third embodiment.

FIG. 13 is a diagram illustrating a power density distribution along a center line of the resistor according to the third embodiment.

FIG. 14 is a plan view of a resistive section according to a fourth embodiment.

FIG. 15 is a plan view illustrating a power density distribution of the resistor according to the fourth embodiment.

FIG. 16 is a diagram illustrating a power density distribution along a center line of the resistor according to the fourth embodiment.

FIG. 17 is a plan view of a resistive section according to a fifth embodiment.

FIG. 18 is a plan view illustrating a power density distribution of the resistor according to the fifth embodiment.

FIG. 19 is a diagram illustrating a power density distribution along the center line of the resistor according to the fifth embodiment.

FIG. 20 is a plan view of a resistive section according to a sixth embodiment.

FIG. 21 is a plan view illustrating a power density distribution of the resistor according to the sixth embodiment.

FIG. 22 is a diagram illustrating a power density distribution along a center line of the resistor according to the sixth embodiment.

FIG. 23 is a plan view of a resistive section according to a seventh embodiment.

FIG. 24 is a sectional view obtained by cutting a resistor illustrated in FIG. 23 along a C-C′ straight line.

FIG. 25 is a plan view illustrating a power density distribution of the resistor according to the seventh embodiment.

FIG. 26 is a diagram illustrating a power density distribution along a center line of the resistor according to the seventh embodiment.

FIG. 27 is a plan view of a resistive section according to an eighth embodiment.

FIG. 28 is a plan view illustrating a power density distribution of the resistor according to the eighth embodiment.

FIG. 29 is a diagram illustrating a power density distribution along the center line of the resistor according to the eighth embodiment.

FIG. 30 is a plan view of a resistive section according to a ninth embodiment.

FIG. 31 is a plan view illustrating a power density distribution of the resistor according to the ninth embodiment.

FIG. 32 is a diagram illustrating a power density distribution along the center line of the resistor according to the ninth embodiment.

FIG. 33 is a plan view of a resistive section according to a tenth embodiment.

FIG. 34 is a plan view illustrating a power density distribution of the resistor according to the tenth embodiment.

FIG. 35 is a diagram illustrating a power density distribution along a center line of the resistor according to the tenth embodiment.

### DESCRIPTION OF EMBODIMENTS

An amplifier according to each embodiment will be described with reference to the accompanying drawings. Components identical or corresponding to each other are indicated by the same reference characters, and repeated description of them is avoided in some cases.

### First Embodiment

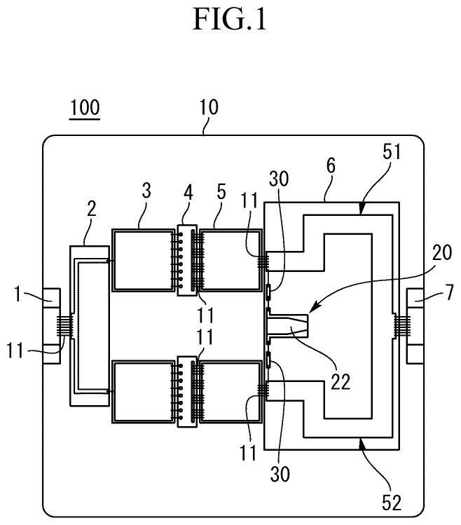

FIG. 1 is a plan view of an amplifier 100 according to a first embodiment. The amplifier 100 is an amplifier including a high-power internal matching type transistor. The amplifier 100 includes an input terminal 1, an output terminal 7, and a pair of amplification paths 51 and 52 provided in parallel between the input terminal 1 and the output terminal 7, each of the pair of amplification paths 51 and 52 including a transistor 4. The amplifier 100 further includes a resistive section 20 that connects the pair of amplification paths 51 and 52.

The input terminal 1 is connected to a substrate 2 by a wire, which is a gold wire. A line that causes a signal input from the input terminal 1 to branch to the amplification paths 51 and 52 is formed on the substrate 2. For each of the amplification paths 51 and 52, a substrate 3 is connected to an output of the substrate 2. The transistor 4 is connected to an output of the substrate 3 by a wire 11. A substrate 5 is connected to an output of the transistor 4 by the wire 11. A substrate 6 is connected to an output of the substrate 5. A line that multiplexes signals of the amplification paths 51 and 52 and outputs a multiplexed signal to the output terminal 7 is formed on the substrate 6. The output terminal 7 is connected to an output of the substrate 6. These components are integrated in a package 10.

The transistor 4 is, for example, an HEMT (High Electron Mobility Transistor) containing GaN (gallium nitride) as a main material. The transistor 4 includes, for example, an SiC (silicon carbide) substrate and a nitride semiconductor layer stacked by epitaxial growth on the SiC substrate and containing GaN (gallium nitride) as a main material. The transistor 4 may be an LDMOS (laterally-diffused metal-oxide semiconductor) applicable to a microwave amplifier. The transistor 4 may be a transistor containing GaAs (gallium arsenide) as a main material, an HBT (Heterojunction Bipolar Transistor), or the like.

The substrates 2, 3, 5, and 6 are matching circuit boards. The substrates 2, 3, and 6 are formed from, for example, aluminum nitride, alumina, or various thin-film ceramics having relative dielectric constants exceeding 30. The substrates 2, 3, and 6 may be formed from glass epoxy, Teflon (registered trademark), a small piece of a printed circuit board containing various low-loss organic materials as a main material, or the like.

A matching circuit formed in each of the substrates 2, 3, and 6 is, for example, a distributed constant circuit configured by a microstrip line formed on a substrate. The matching circuit is not limited to the microstrip. The distributed constant circuit and a concentrated constant circuit may be concurrently used.

The package 10 is, for example, a hollow hermetic package made of metal. A not-illustrated lid for hermetically sealing the substrates 2, 3, 5, and 6 and the transistor 4 is provided in the package 10. Note that, in FIG. 1, a state in which the lid is removed is illustrated in order to explain an internal structure of the amplifier 100.

Microwave power input to the amplifier 100 from the outside is input from the input terminal 1 to a gate of the transistor 4 via the substrate 2 and the substrate 3. The microwave power amplified by the transistor 4 is output from a drain of the transistor 4 to the outside of the amplifier 100 via the substrate 5, the substrate 6, and the output terminal 7. The substrate 2 acts as a microwave distribution circuit. The substrate 6 acts as a microwave combination circuit. The substrate 3 and the substrate 5 act as an impedance transformer circuit.

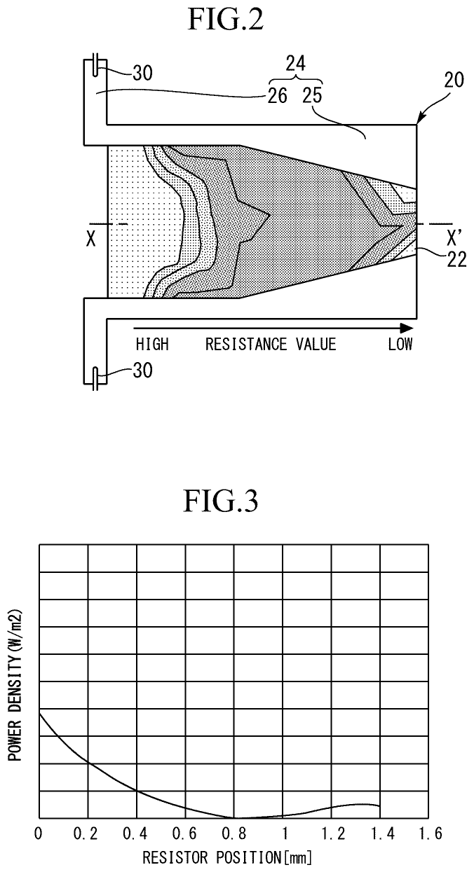

FIG. 2 is a plan view illustrating a power density distribution of a resistor 22 according to the first embodiment. First, the structure of the resistive section 20 is explained with reference to FIG. 2. The resistive section 20 is provided, for example, on the substrate 6 that is a matching circuit board provided on an output side of the transistor 4. The resistive section 20 includes the resistor 22, the width of which is, compared to on one end side, narrower on the other end side. The resistor 22 is formed of, for example, a thin film of Ta2N (tantalum nitride) that shows a relatively high resistivity.

A pair of conductor patterns 24 electrically connected to the resistor 22 is provided on both the sides in the width direction of the resistor 22. On one end side of the resistor 22, a pair of wirings 30 connects the pair of conductor patterns 24 and the pair of amplification paths 51 and 52. Specifically, the pair of wirings 30 is respectively connected to signal lines of the pair of amplification paths 51 and 52 formed on the substrate 6. The wirings 30 are, for example, wiring patterns on the substrate 6. The conductor patterns 24 and the wirings 30 are formed by, for example, stacking nichrome (NiCr) and gold (Au) in order from the substrate 6 side.

Note that an X-X′ straight line in FIG. 2 is a center line extending from one end to the other end of the resistor 22. A direction perpendicular to the X-X′ straight line is the width direction. In the following explanation, the X-X′ straight line is sometimes simply referred to as center line. One end side indicates a side where the resistor 22 is wide and the other end side indicates a side where the resistor 22 is narrow.

For example, at least a part of the resistor 22 is taper-shaped. Accordingly, the resistor 22 has a width which is, compared to on one end side, narrower on the other end side. In an example illustrated in FIG. 2, a part of the other end side in the resistor 22 is taper-shaped.

The pair of conductor patterns 24 is provided from one end to the other end of the resistor 22. Each of the pair of conductor patterns 24 includes a first portion 25 provided along one end to the other end of the resistor 22 and a second portion 26 extending from the first portion 25 on one end side. That is, the conductor pattern 24 is L-shaped. Each of the pair of wirings 30 is connected to the second portion 26. Each of the pair of conductor patterns 24 has a width which is, compared to on one end side, wider on the other end side. Accordingly, a combined width of the pair of conductor patterns 24 and the resistor 22 is constant as a whole.

The shape of the conductor pattern 24 illustrated in FIG. 2 is an example. For example, the conductor pattern 24 may not be L-shaped. If resistance is small, the conductor pattern 24 may be a linear pattern or, for example, the width of the conductor pattern 24 and the width of the resistor 22 may be the same degree. The conductor pattern 24 may not be provided from one end to the other end of the resistor 22. Each of the pair of conductor patterns 24 may not have a width which is, compared to on one end side, wider on the other end side. The combined width of the pair of conductor patterns 24 and the resistor 22 may not be constant as a whole. Further, a position where the wiring 30 is connected to the conductor pattern 24 is not limited to the end portion on one end side of the conductor pattern 24 and may be a position shifted to the center from the end portion on one end side of the conductor pattern 24.

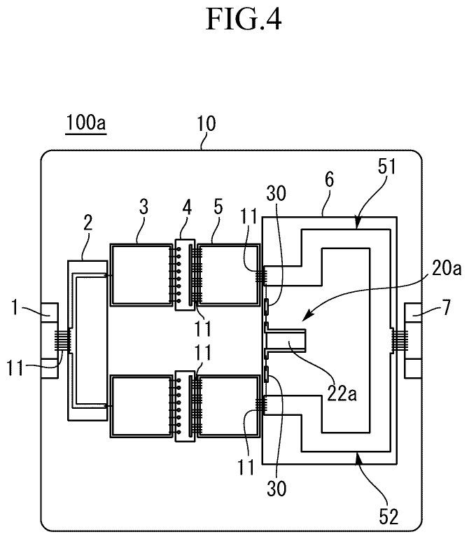

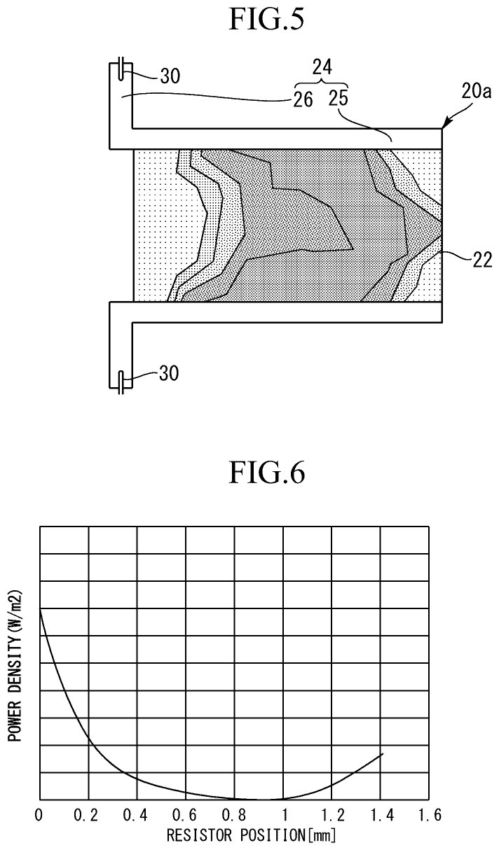

Subsequently, an effect of the present embodiment is explained using a comparative example. FIG. 4 is a plan view of an amplifier 100a according to the comparative example. FIG. 5 is a plan view illustrating a power density distribution of a resistor 22a according to the comparative example. The comparative example is different from the first embodiment in the structure of a resistive section 20a. In the comparative example, the width of the resistor 22a included in the resistive section 20a is constant. In the plan views illustrating the power density distributions such as FIGS. 2 and 5, the power density distributions are indicated by shades of colors.

The amplifier 100a includes two transistors 4 and includes two amplification paths leading from an input to an output. It is known that an amplifier including a plurality of amplification paths in this way can cause loop oscillation. The resistive section 20a is called stabilization resistor as well and is provided between the amplification paths such that a loop gain can be reduced and the loop oscillation can be prevented.

FIG. 6 is a diagram illustrating a power density distribution along a center line of the resistor 22a according to the comparative example. In FIG. 6, power density consumed by the resistor 22a on the center line is indicated by a relative value. A positive direction of the horizontal axis in FIG. 6 is a direction from one end to the other end of the resistor 22a. When a rectangular stabilization resistor having uniform thickness is used as in the comparative example, a power density distribution of the stabilization resistor is not uniform and a location at which electric power is excessively concentrated has appeared. In this case, it is also likely that the resistor 22a is discolored or burned. In an example illustrated in FIG. 6, power concentration has occurred on one end side of the resistor 22a, that is, a side to which the wiring 30 is connected.

In contrast, in the present embodiment, the resistor 22, the width of which is, compared to on one end side, narrower on the other end side, is adopted such that a power density distribution of the resistive section 20 becomes uniform. That is, a resistance value per unit length in the resistor 22 is made to decrease further away from the wiring 30 on one end side. FIG. 3 is a diagram illustrating a power density distribution along the center line of the resistor 22 according to the first embodiment. In the present embodiment, compared with the comparative example, a change in power density in the resistive section 20 is suppressed. Compared with the comparative example, power density particularly in a part on one end side where power concentration easily occurs has decreased. Therefore, it is possible to prevent appearance of a location at which a power density distribution is excessively concentrated in the resistor 22 and prevent burning or discoloration of the resistive section 20.

In contrast to the comparative example, the amplifier 100 in the present embodiment can be obtained by changing only the shape of the resistive section 20 without correcting a matching circuit itself. Electric power easily reaches the other end side by widening the conductor pattern 24 as the conductor pattern 24 is further away from a connection point to the wiring 30. For this reason, it is possible to obtain an effect of dispersing the electric power of the resistive section 20.

In the present embodiment, loop oscillation is cited as an example of oscillation. The resistive section 20 in the present embodiment may be adopted as a stabilization resistor that suppresses not only the loop oscillation but also, for example, oscillation due to load fluctuation or ½ harmonic oscillation. The present embodiment can be applied in a situation in which a location at which electric power is excessively concentrated can be present in a resistive section.

The resistive section 20 only has to connect the pair of amplification paths 51 and 52 and may be provided in a part other than the substrate 6 on the output side. For example, the resistive section 20 may be provided on the substrate 2 on the input side. Note that electric power consumed by the resistive section 20 is larger when the resistive section 20 is connected to the output side. For this reason, a higher effect can be obtained when the resistive section 20 in the present embodiment is applied to the output side. The amplification paths 51 and 52 provided in the amplifier 100 are not limited to two amplification paths and only have to be a plurality of amplification paths.

These modifications can be appropriately applied to amplifiers according to embodiments below. Meanwhile, for the amplifiers according to the embodiments below, dissimilarities with the first embodiment will mainly be explained as they have many similarities with the first embodiment.

### Second Embodiment

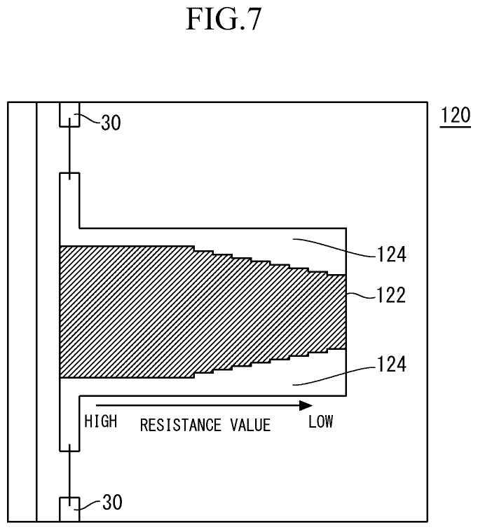

FIG. 7 is a plan view of a resistive section 120 according to a second embodiment. The present embodiment is different from the first embodiment in the structure of the resistive section 120. The other structure is the same as the structure in the first embodiment. The resistive section 120 includes a resistor 122, the width of which is, compared to on one end side, narrower on the other end side. Specifically, the resistor 122 includes a portion narrowed stepwise from one end toward the other end. A pair of conductor patterns 124 electrically connected to the resistor 122 is provided on both the sides in the width direction of the resistor 122. On one end side of the resistor 122, the pair of wirings 30 connects the pair of conductor patterns 124 and the pair of amplification paths 51 and 52.

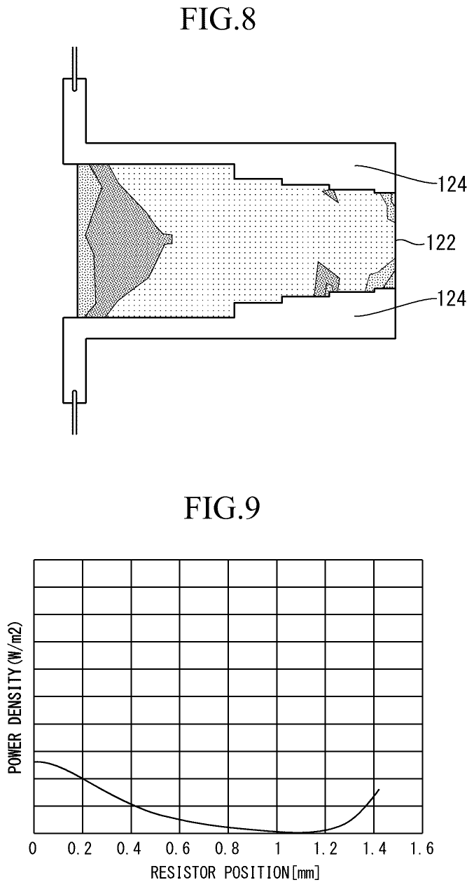

FIG. 8 is a plan view illustrating a power density distribution of the resistor 122 according to the second embodiment. FIG. 9 is a diagram illustrating a power density distribution along a center line of the resistor 122 according to the second embodiment. In the present embodiment as well, a resistance value per unit length in the resistor 122 is made to decrease further away from the wiring 30 on one end side. Accordingly, as illustrated in FIGS. 8 and 9, it is possible to suppress a change in power density in the resistive section 120. Power density particularly in a part on one end side where power concentration easily occurs can be reduced. Therefore, it is possible to prevent appearance of a location at which a power density distribution is excessively concentrated in the resistor 122.

### Third Embodiment

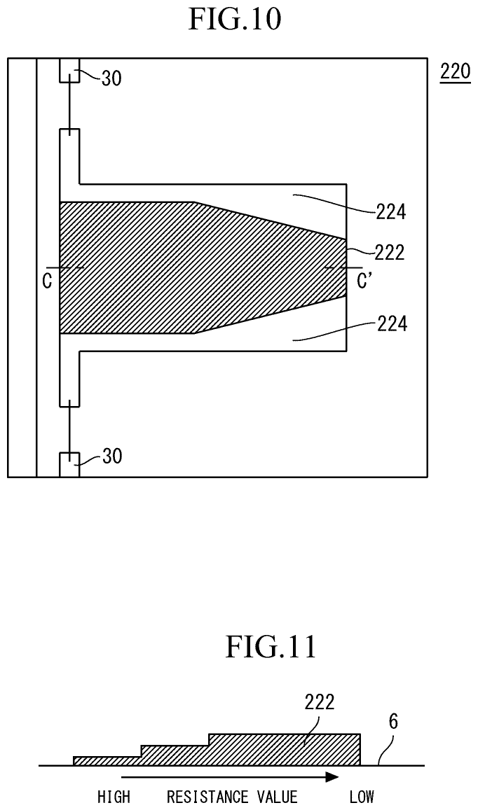

FIG. 10 is a plan view of a resistive section 220 according to a third embodiment. FIG. 11 is a sectional view obtained by cutting a resistor 222 illustrated in FIG. 10 along a C-C′ straight line. The present embodiment is different from the first embodiment in the structure of the resistive section 220. The other structure is the same as the structure in the first embodiment. The resistive section 220 includes the resistor 222, the width of which is, compared to on one end side, narrower on the other end side. In plan view, the shape of the resistor 222 is the same as the shape of the resistor 22. The resistor 222 has a thickness which is, compared to on one end side, thicker on the other end side. Specifically, the thickness of the resistor 222 increases stepwise from one end toward the other end.

A pair of conductor patterns 224 electrically connected to the resistor 222 is provided on both the sides in the width direction of the resistor 222. On one end side of the resistor 222, the pair of wirings 30 connects the pair of conductor patterns 224 and the pair of amplification paths 51 and 52.

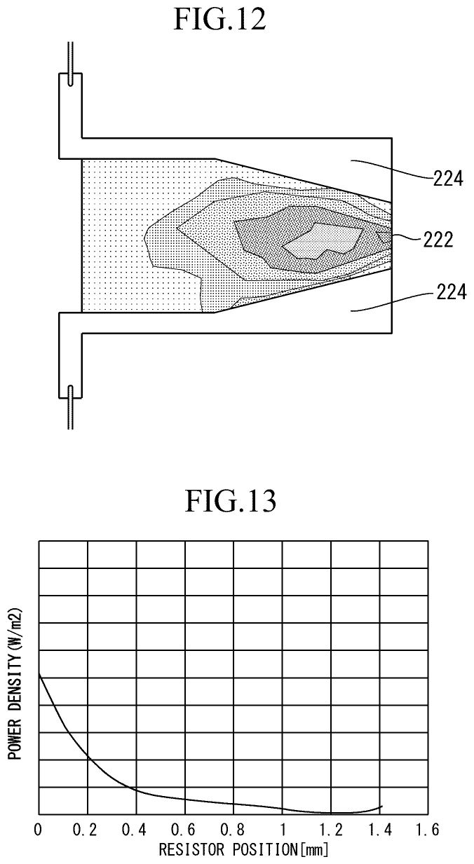

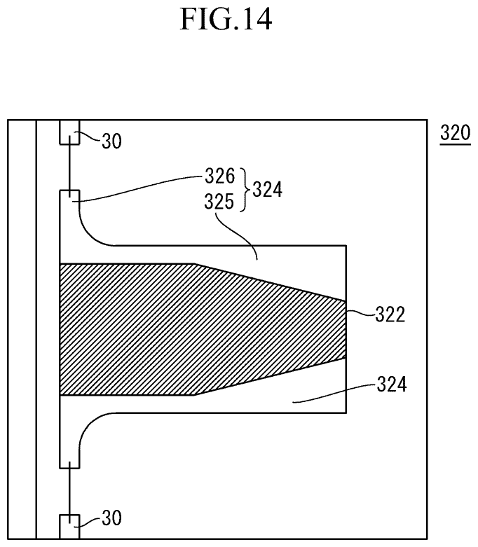

FIG. 12 is a plan view illustrating a power density distribution of the resistor 222 according to the third embodiment. FIG. 13 is a diagram illustrating a power density distribution along a center line of the resistor 222 according to the third embodiment. In the present embodiment, by changing the width and the thickness of the resistor 222, a resistance value per unit length in the resistor 222 is made to decrease further away from the wiring 30 on one end side. Accordingly, as illustrated in FIGS. 12 and 13, it is possible to suppress a change in power density in the resistive section 220. Power density particularly in a part on one end side where power concentration easily occurs can be reduced. Therefore, it is possible to prevent appearance of a location at which a power density distribution is excessively concentrated in the resistor 222.

Note that the thickness of the resistor 222 may change continuously without being limited to changing stepwise. A plane shape of the resistor 122 in the second embodiment and the present embodiment may be combined.

### Fourth Embodiment

FIG. 14 is a plan view of a resistive section 320 according to a fourth embodiment. The present embodiment is different from the first embodiment in the structure of the resistive section 320. The other structure is the same as the structure in the first embodiment. The resistive section 320 includes a resistor 322, the width of which is, compared to on one end side, narrower on the other end side. A pair of conductor patterns 324 electrically connected to the resistor 322 is provided on both the sides in the width direction of the resistor 322. In the present embodiment, the width of second portions 326 of the conductor patterns 324 continuously increases toward first portions 325. On one end side of the resistor 322, the pair of wirings 30 connects the second portions 326 of the pair of conductor patterns 324 and the pair of amplification paths 51 and 52.

In the present embodiment as well, by changing the width of the resistor 322, a resistance value per unit length in the resistor 322 is made to decrease further away from the wiring 30 on one end side. Further, in the present embodiment, the width of the second portions 326 of the conductor patterns 324 continuously increases toward the first portions 325. That is, corners of the conductor patterns 324 are formed in a fillet shape. This makes it easy to distribute electric power even to a part far from a part to which the wiring 30 is connected in the resistor 322.

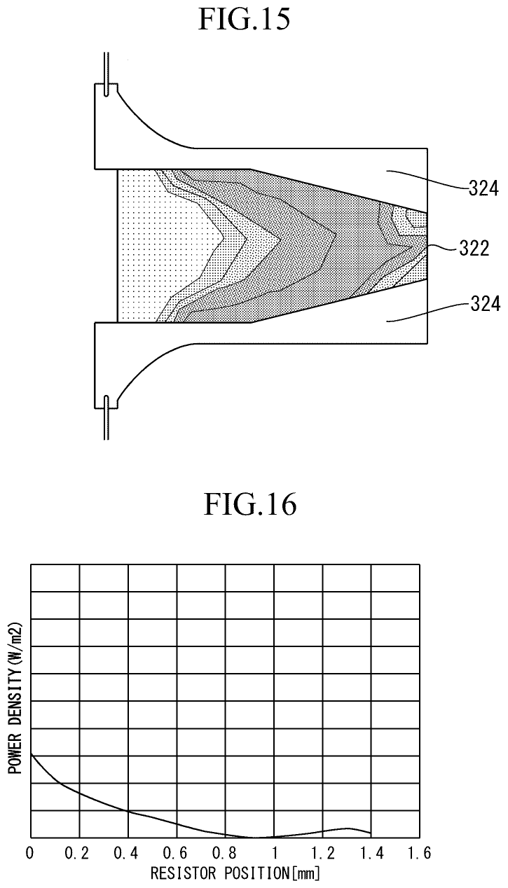

FIG. 15 is a plan view illustrating a power density distribution of the resistor 322 according to the fourth embodiment. FIG. 16 is a diagram illustrating a power density distribution along a center line of the resistor 322 according to the fourth embodiment. With the structure in the present embodiment, it is possible to suppress a change in power density in the resistive section 320. Power density particularly in a part on one end side where power concentration easily occurs can be reduced. Therefore, it is possible to prevent appearance of a location at which a power density distribution is excessively concentrated in the resistor 322.

Note that the conductor pattern 324 in the present embodiment may be applied to not only the first embodiment but also the second and third embodiments.

### Fifth Embodiment

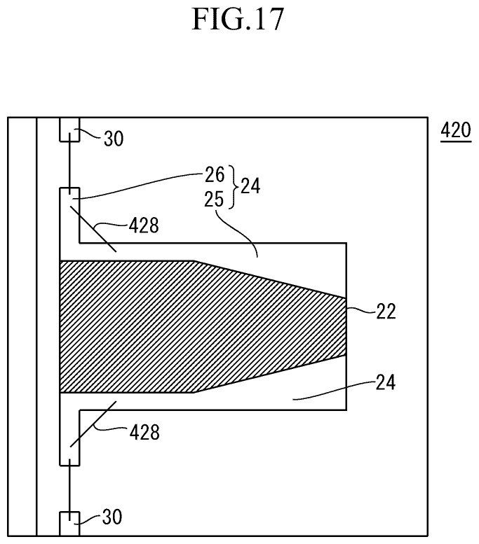

FIG. 17 is a plan view of a resistive section 420 according to a fifth embodiment. The present embodiment is different from the first embodiment in that the resistive section 420 includes a wire 428 that connects the first portion 25 and the second portion 26 of the conductor pattern 24. The other structure is the same as the structure in the first embodiment.

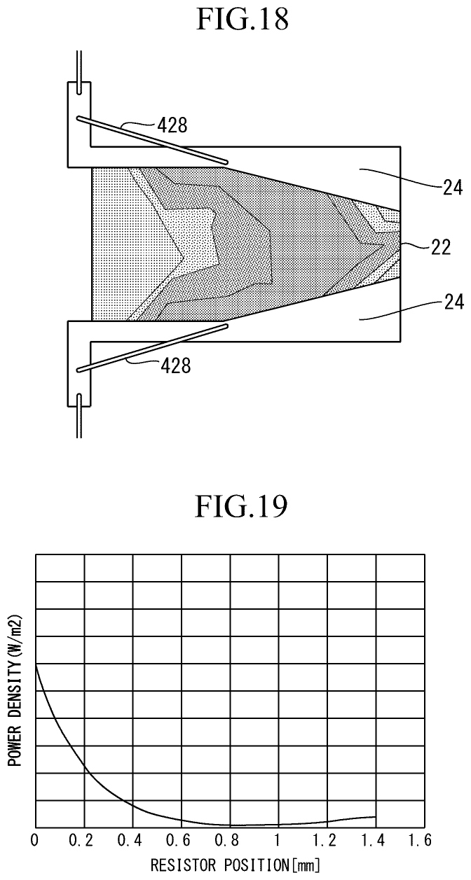

FIG. 18 is a plan view illustrating a power density distribution of the resistor 22 according to the fifth embodiment. FIG. 19 is a diagram illustrating a power density distribution along the center line of the resistor 22 according to the fifth embodiment. In the present embodiment, the wire 428, which is a gold wire, is connected to a corner of the conductor pattern 24. For this reason, electric power is easily distributed to a part far from a part to which the wiring 30 is connected in the resistor 22. Accordingly, as illustrated in FIGS. 18 and 19, it is possible to suppress a change in power density in the resistive section 420. Power density particularly in a part on one end side where power concentration easily occurs can be reduced. Therefore, it is possible to prevent appearance of a location at which a power density distribution is excessively concentrated in the resistor 22.

A connecting part of the wire 428 is, for example, one end side of the first portion 25. The connecting part is not limited to this. The wire 428 may be connected to the center or the other end side of the first portion 25. Note that the wire 428 may be applied to not only the first embodiment but also the second, third, and fourth embodiments.

### Sixth Embodiment

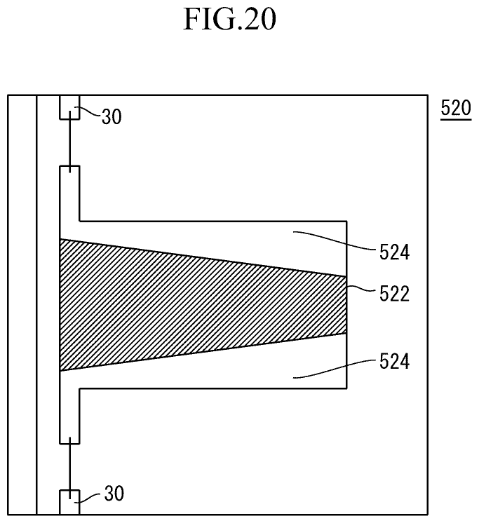

FIG. 20 is a plan view of a resistive section 520 according to a sixth embodiment. The present embodiment is different from the first embodiment in the structure of the resistive section 520. The other structure is the same as the structure in the first embodiment. The resistive section 520 includes a resistor 522, the width of which is, compared to on one end side, narrower on the other end side. Specifically, the resistor 522 is taper-shaped from one end to the other end. A pair of conductor patterns 524 electrically connected to the resistor 522 is provided on both the sides in the width direction of the resistor 522. The conductor pattern 524 has a taper shape that is wider as the conductor pattern 524 is further away from a part to which the wiring 30 is connected. On one end side of the resistor 522, the pair of wirings 30 connects the pair of conductor patterns 524 and the pair of amplification paths 51 and 52.

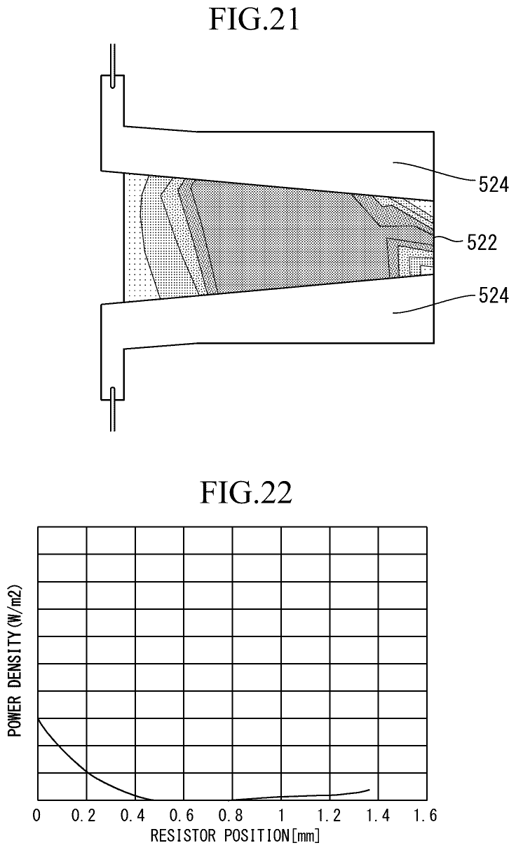

FIG. 21 is a plan view illustrating a power density distribution of the resistor 522 according to the sixth embodiment. FIG. 22 is a diagram illustrating a power density distribution along a center line of the resistor 522 according to the sixth embodiment. In the present embodiment as well, a resistance value per unit length in the resistor 522 is made to decrease further away from the wiring 30 on one end side. Electric power easily reaches the other end side by widening the conductor pattern 524 as the conductor pattern 524 is further away from a connection point to the wiring 30. Accordingly, it is possible to obtain an effect of dispersing electric power of the resistive section 520. With the structure explained above, as illustrated in FIGS. 21 and 22, it is possible to suppress a change in power density in the resistive section 520. Power density particularly in a part on one end side where power concentration easily occurs can be reduced. Therefore, it is possible to prevent appearance of a location at which a power density distribution is excessively concentrated in the resistor 522.

The present embodiment and the second embodiment may be combined to narrow the resistor 522 stepwise from one end to the other end. The change in the thickness in the third embodiment or the conductor pattern 324 in the fourth embodiment may be applied to the present embodiment.

### Seventh Embodiment

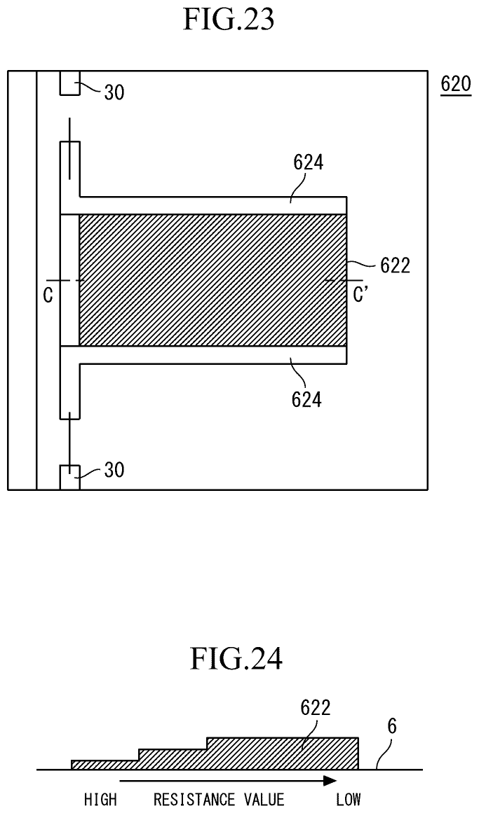

FIG. 23 is a plan view of a resistive section 620 according to a seventh embodiment. FIG. 24 is a sectional view obtained by cutting a resistor 622 illustrated in FIG. 23 along a C-C′ straight line. The present embodiment is different from the first embodiment in the structure of the resistive section 620. The other structure is the same as the structure in the first embodiment. The resistive section 620 includes the resistor 622, the thickness of which is, compared to on one end side, thicker on the other end side. Specifically, the thickness of the resistor 622 increases stepwise from one end toward the other end. In a plan view, the resistor 622 is, for example, a rectangle having constant width.

A pair of conductor patterns 624 electrically connected to the resistor 622 is provided on both the sides in a direction intersecting a direction from one end toward the other end of the resistor 622. Note that, in the present embodiment, one end side indicates a side where the resistor 622 is thin and the other end side indicates a side where the resistor 622 is thick. On one end side of the resistor 622, the pair of wirings 30 connects the pair of conductor patterns 624 and the pair of amplification paths 51 and 52.

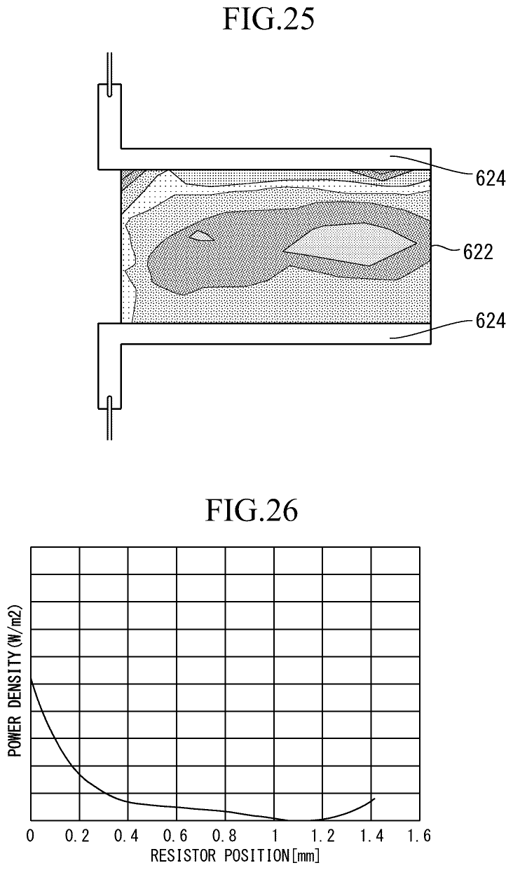

FIG. 25 is a plan view illustrating a power density distribution of the resistor 622 according to the seventh embodiment. FIG. 26 is a diagram illustrating a power density distribution along a center line of the resistor 622 according to the seventh embodiment. In the present embodiment, by changing the width of the resistor 622, a resistance value per unit length in the resistor 622 is made to decrease further away from the wiring 30 on one end side. Accordingly, as illustrated in FIGS. 25 and 26, it is possible to suppress a change in power density in the resistive section 620. Power density particularly in a part on one end side where power concentration easily occurs can be reduced. Therefore, it is possible to prevent appearance of a location at which a power density distribution is excessively concentrated in the resistor 622.

Note that the thickness of the resistor 622 may change continuously without being limited to changing stepwise. The conductor pattern 324 in the fourth embodiment or the wire 428 in the fifth embodiment may be applied to the present embodiment.

### Eighth Embodiment

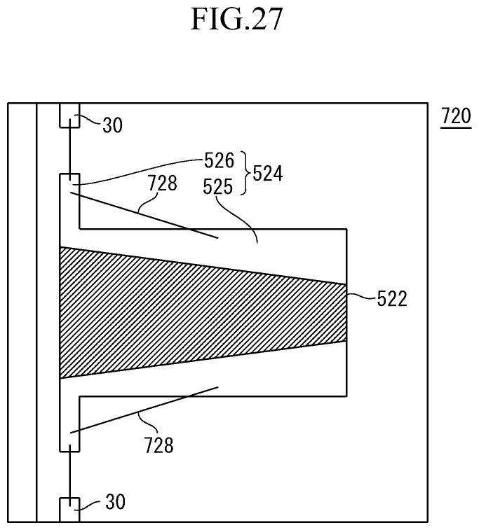

FIG. 27 is a plan view of a resistive section 720 according to an eighth embodiment. The present embodiment is different from the sixth embodiment in that the resistive section 720 includes a wire 728 that connects a first portion 525 and a second portion 526 of the conductor pattern 524. The other structure is the same as the structure in the sixth embodiment. The wire 728 connects, for example, the center in a direction from one end toward the other end in the first portion 525 and the second portion 526.

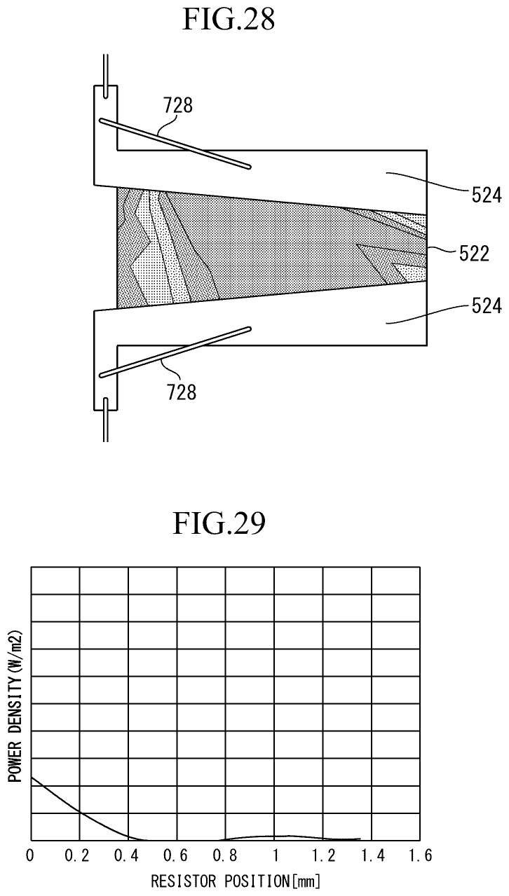

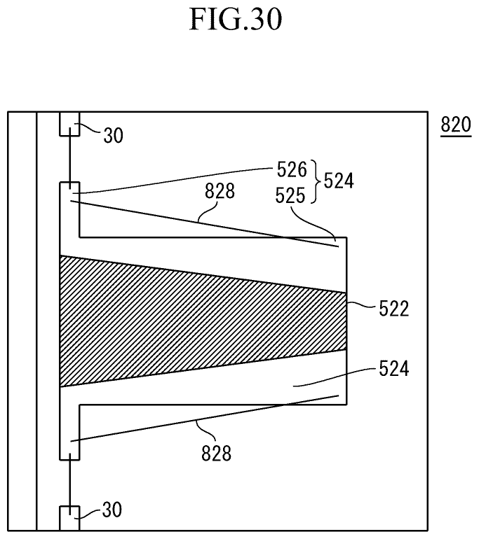

FIG. 28 is a plan view illustrating a power density distribution of the resistor 522 according to the eighth embodiment. FIG. 29 is a diagram illustrating a power density distribution along the center line of the resistor 522 according to the eighth embodiment. In the present embodiment, the first portion 525 and the second portion 526 of the conductor pattern 524 are connected by the wire 728, which is a gold wire. This makes it easy to distribute electric power even to a part far from a part to which the wiring 30 is connected in the resistor 522. In particular, this effect can be improved by connecting the wire 728 to a center separated from the part to which the wiring 30 is connected in the first portion 525.

Accordingly, as illustrated in FIGS. 28 and 29, it is possible to suppress a change in power density in the resistive section 720. Power density particularly in a part on one end side where power concentration easily occurs can be reduced. Therefore, it is possible to prevent appearance of a location at which a power density distribution is excessively concentrated in the resistor 522.

The center of the first portion 525 to which the wire 728 is connected may be a middle portion at the time when the first portion 525 is equally divided into three in the longitudinal direction. The wire 728 may be connected to one end side or the other end side of the first portion 525. The wire 728 in the present embodiment may be applied to not only the sixth embodiment but also the first to fourth and seventh embodiments.

### Ninth Embodiment

FIG. 30 is a plan view of a resistive section 820 according to a ninth embodiment. The present embodiment is different from the eighth embodiment in a part to which a wire 828 is connected. The other structure is the same as the structure in the eighth embodiment. The wire 828 connects the end portion on the other end side of the first portion 525 and the second portion 526.

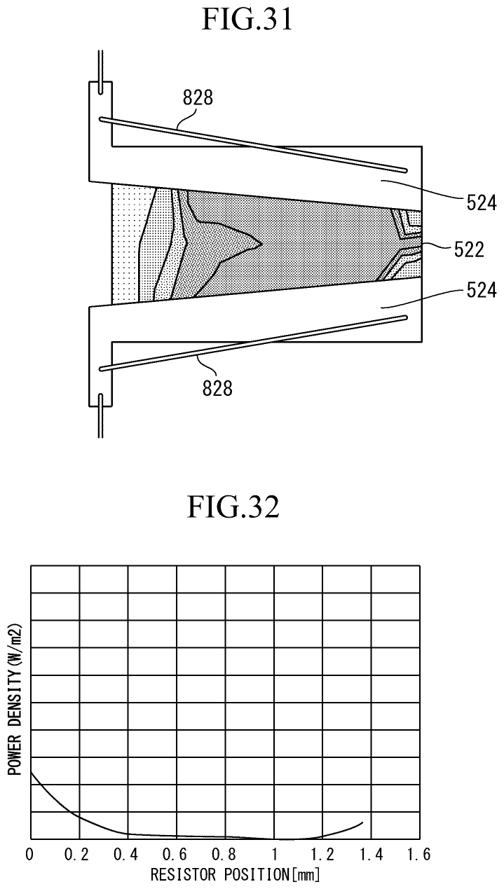

FIG. 31 is a plan view illustrating a power density distribution of the resistor 522 according to the ninth embodiment. FIG. 32 is a diagram illustrating a power density distribution along the center line of the resistor 522 according to the ninth embodiment. In the present embodiment, the first portion 525 and the second portion 526 of the conductor pattern 524 are connected by the wire 828, which is a gold wire. This makes it easy to distribute electric power even to a part far from a part to which the wiring 30 is connected in the resistor 522. In particular, this effect can be improved by connecting the wire 828 to an end portion separated from the part to which the wiring 30 is connected in the first portion 525.

Accordingly, it is possible to suppress a change in power density in the resistive section 820 as illustrated in FIGS. 31 and 32. Power density particularly in a part on one end side where power concentration easily occurs can be reduced. Therefore, it is possible to prevent appearance of a location at which a power density distribution is excessively concentrated in the resistor 522.

The wire 828 in the present embodiment may be applied to not only the sixth embodiment but also the first to fourth and seventh embodiments.

### Tenth Embodiment

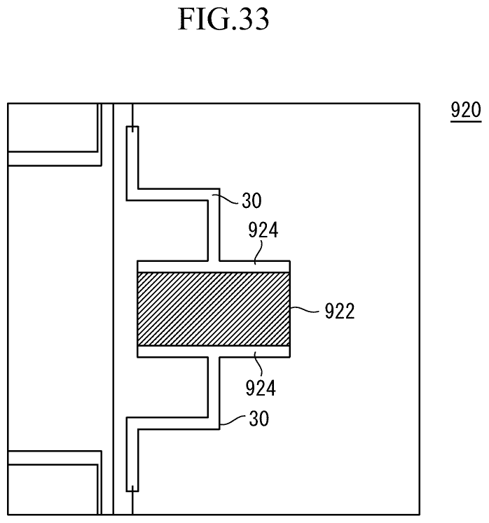

FIG. 33 is a plan view of a resistive section 920 according to a tenth embodiment. The present embodiment is different from the first embodiment in the structure of the resistive section 920. The other structure is the same as the structure in the first embodiment. The resistor section 920 includes a resistor 922. In a plan view, a resistor 922 is, for example, a rectangle having constant width. The thickness of the resistor 922 may be constant. The resistor 922 may have a constant resistance value per unit length.

A pair of conductor patterns 924 electrically connected to the resistor 922 is provided on both the sides in a direction intersecting a direction from one end toward the other end of the resistor 922. The conductor patterns 924 is, for example, linear. The pair of wirings 30 connects the pair of conductor patterns 924 and the pair of amplification paths 51 and 52 in the center in the direction from one end to the other end of the resistor 922.

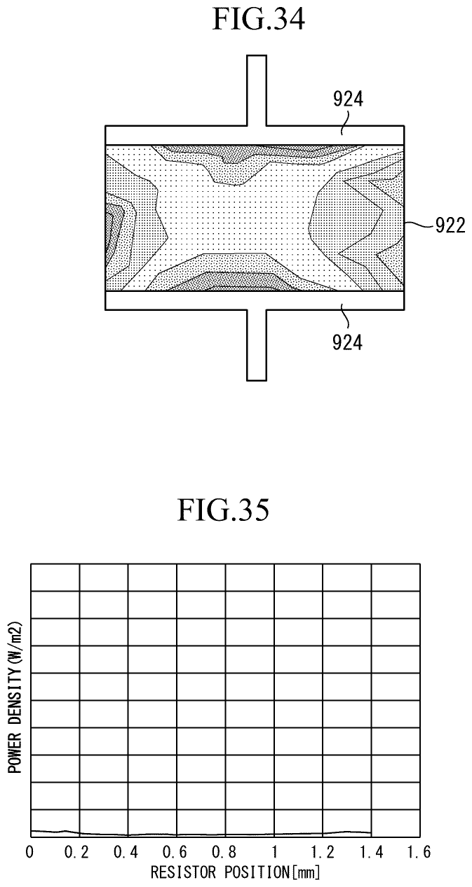

FIG. 34 is a plan view illustrating a power density distribution of the resistor 922 according to the tenth embodiment. FIG. 35 is a diagram illustrating a power density distribution along a center line of the resistor 922 according to the tenth embodiment. In the present embodiment, the pair of wirings 30 is connected to a position corresponding to the center of the resistor 922 in the conductor pattern 924. For this reason, compared with the comparative example illustrated in FIG. 4, it is possible to reduce the distance from the wiring 30 to the end portion of the resistor 922. Accordingly, as illustrated in FIGS. 34 and 35, it is possible to suppress a change in power density in the resistive section 920. Power density particularly in a part at an end portion where power concentration easily occurs can be reduced. Therefore, it is possible to prevent appearance of a location at which a power density distribution is excessively concentrated in the resistor 922.

When the length of the resistor 922 is represented as L, the center, which is a connecting part of the wiring 30, is a position of L/2 from the end portion of the resistor 922. Note that the center of the resistor 922 may not be the position of L/2 in a strict sense. For example, the wiring 30 may be connected to a middle part at the time when the resistor 922 is equally divided into three in the longitudinal direction.

Meanwhile, technical features explained in each embodiment may be appropriately combined to use.

Hereinafter, various aspects of the present disclosure will be collectively described as appendixes.

### Appendix 1

An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
   a resistor having a width which is, compared to on one end side, narrower on another end side;
   a pair of conductor patterns provided on both sides in a width direction of the resistor and electrically connected to the resistor; and
   a pair of wirings that connects the one end side of the pair of conductor patterns and the pair of amplification paths.

### Appendix 2

The amplifier according to appendix 1, wherein the pair of conductor patterns is provided from the one end to the another end of the resistor.

### Appendix 3

The amplifier according to appendix 1 or 2, wherein each of the pair of conductor patterns has a width which is, compared to on the one end side, wider on the another end side.

### Appendix 4

The amplifier according to any one of appendixes 1 to 3, further comprising a matching circuit board provided on an output side of the transistor, wherein
the resistive section is provided on the matching circuit board.

### Appendix 5

The amplifier according to any one of appendixes 1 to 4, wherein at least a part of the resistor is taper-shaped.

### Appendix 6

The amplifier according to appendix 5, wherein the resistor is taper-shaped from the one end to the another end.

### Appendix 7

The amplifier according to any one of appendixes 1 to 4, wherein the resistor includes a portion narrowed stepwise from the one end toward the another end.

### Appendix 8

The amplifier according to any one of appendixes 1 to 7, wherein the resistor has a thickness which is, compared to on the one end side, thicker on the another end side.

### Appendix 9

The amplifier according to any one of appendixes 1 to 8, wherein
each of the pair of conductor patterns includes:
a first portion provided along the resistor from the one end to the another end; and
a second portion extending from the first portion on the one end side, and
each of the pair of wirings is connected to the second portion.

### Appendix 10

The amplifier according to appendix 9, wherein width of the second portion continuously increases toward the first portion.

### Appendix 11

The amplifier according to appendix 9 or 10, further comprising a wire that connects the first portion and the second portion.

### Appendix 12

The amplifier according to appendix 11, wherein
the resistor is taper-shaped from the one end to the another end, and
the wire connects a center in a direction from the one end toward the another end in the first portion and the second portion.

### Appendix 13

The amplifier according to appendix 11, wherein
the resistor is taper-shaped from the one end to the another end, and
the wire connects an end portion on the another end side in the first portion and the second portion.

### Appendix 14

An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
   a resistor having a thickness which is, compared to on one end side, thicker on another end side;
   a pair of conductor patterns provided on both sides in a direction intersecting a direction from the one end toward the another end of the resistor and electrically connected to the resistor; and
   a pair of wirings that connects the one end side of the pair of conductor patterns and the pair of amplification paths.

### Appendix 15

An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
   a resistor;
   a pair of conductor patterns provided on both sides in a direction intersecting a direction from one end toward another end of the resistor and electrically connected to the resistor; and
   a pair of wirings that connects the pair of conductor patterns and the pair of amplification paths in a center in the direction from the one end toward the another end of the resistor.

In the amplifier according to the first disclosure, as compared to one end side, since the other end side is made narrower in the resistor, it is possible to prevent appearance of a location at which a power density distribution is excessively concentrated.

In the amplifier according to the second disclosure, as compared to one end side, since the other end side is made thicker in the resistor, it is possible to prevent appearance of a location at which a power density distribution is excessively concentrated.

In the amplifier according to the third disclosure, the pair of wirings connects the pair of conductor patterns and the pair of amplification paths in a center in the direction from the one end toward the another end of the resistor. For this reason, it is possible to prevent appearance of a location at which a power density distribution is excessively concentrated.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-064992, filed on Apr. 12, 2024 including specification, claims, drawings and summary, on which the Convention priority of the present application is based, are incorporated herein by reference in its entirety.

1. An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
a resistor having a width which is, compared to on one end side, narrower on another end side;
a pair of conductor patterns provided on both sides in a width direction of the resistor and electrically connected to the resistor; and
a pair of wirings that connects the one end side of the pair of conductor patterns and the pair of amplification paths.

2. The amplifier according to claim 1, wherein the pair of conductor patterns is provided from the one end to the another end of the resistor.

3. The amplifier according to claim 1, wherein each of the pair of conductor patterns has a width which is, compared to on the one end side, wider on the another end side.

4. The amplifier according to claim 1, further comprising a matching circuit board provided on an output side of the transistor, wherein
the resistive section is provided on the matching circuit board.

5. The amplifier according to claim 1, wherein at least a part of the resistor is taper-shaped.

6. The amplifier according to claim 5, wherein the resistor is taper-shaped from the one end to the another end.

7. The amplifier according to claim 1, wherein the resistor includes a portion narrowed stepwise from the one end toward the another end.

8. The amplifier according to claim 1, wherein the resistor has a thickness which is, compared to on the one end side, thicker on the another end side.

9. The amplifier according to claim 1, wherein
each of the pair of conductor patterns includes:
a first portion provided along the resistor from the one end to the another end; and
a second portion extending from the first portion on the one end side, and
each of the pair of wirings is connected to the second portion.

10. The amplifier according to claim 9, wherein width of the second portion continuously increases toward the first portion.

11. The amplifier according to claim 9, further comprising a wire that connects the first portion and the second portion.

12. The amplifier according to claim 11, wherein
the resistor is taper-shaped from the one end to the another end, and
the wire connects a center in a direction from the one end toward the another end in the first portion and the second portion.

13. The amplifier according to claim 11, wherein
the resistor is taper-shaped from the one end to the another end, and
the wire connects an end portion on the another end side in the first portion and the second portion.

14. An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
a resistor having a thickness which is, compared to on one end side, thicker on another end side;
a pair of conductor patterns provided on both sides in a direction intersecting a direction from the one end toward the another end of the resistor and electrically connected to the resistor; and
a pair of wirings that connects the one end side of the pair of conductor patterns and the pair of amplification paths.

15. An amplifier comprising:
an input terminal;
an output terminal;
a pair of amplification paths provided in parallel between the input terminal and the output terminal, each of the pair of amplification paths including a transistor; and
a resistive section that connects the pair of amplification paths, wherein
the resistive section includes:
a resistor;
a pair of conductor patterns provided on both sides in a direction intersecting a direction from one end toward another end of the resistor and electrically connected to the resistor; and
a pair of wirings that connects the pair of conductor patterns and the pair of amplification paths in a center in the direction from the one end toward the another end of the resistor.
